(19) United States
(12) Patent Application Publication
(10) Pub. No.: US 2007/0176260 A1
(43) Pub. Date: Aug. 2, 2007

(54) Active area resistors and methods for making the same

(76) Inventor: Kunal R. Parekh, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/343,925

(22) Filed: Jan. 31, 2006

(51) Int. Cl. H01L 29/00; H01L 21/20

(52) U.S. Cl. 257/536; 438/382; 438/385; 257/537

(57) ABSTRACT

Resistors used with a semiconductor device may include resistors defined by patterned layers of polysilicon or metal defining diffusion regions within patterns of the patterned layers such that the number of squares of resistance of the resistors may be increased and dishing of glass or other material layers over the resistors are reduced or eliminated. Methods of forming such resistors may include the formation of a polysilicon or metal layer, the patterning of the layer, doping of a semiconductor substrate exposed by the pattern to form a diffused region, and connection of the diffused region to the necessary contacts to form a resistor.

### BACKGROUND OF THE INVENTION

1. Field of the Invention

The invention relates to resistors on semiconductor devices and methods for the formation of such resistors. More particularly, the invention relates to methods for forming resistive areas on a semiconductor device and the resistive structures formed by those methods.

2. Technical Background

Resistors and resistive devices are commonly used with semiconductor devices. For example, semiconductor devices may employ resistors formed by the diffusion of one or more dopants in a silicon substrate of a semiconductor device. In other instances, resistors may be formed of thin-films deposited on a semiconductor wafer surface. In either instance, it is preferred that the semiconductor fabrication processes allow the formation of the desired resistors or resistive structures without the addition of excessive processing steps and while maintaining the integrity of the semiconductor device.

The amount of resistance in a resistor may depend upon the length of the resistive structure, the width of the resistive structure, the depth of the diffusion, and the resistive value of the material from which the resistor is formed. The resistance of a resistor in a semiconductor device may be calculated by multiplying the number of squares of the resistor by the sheet resistance of the resistor structure. The squares of the resistor are a ratio of the length of the resistor (L) to the width of the resistor (W) and the sheet resistance defines the resistance of the resistor in ohms per square. For example, a resistor having a sheet resistance of 50 ohms per square will have a total resistance based upon the number of squares in the resistor. If the resistor is five squares, the total resistance of the resistor is 250 ohms; if the resistor is ten squares, the total resistance of the resistor is 500 ohms. Methods for calculating the amount of resistance of a resistor using squares of resistance are well known and are commonly used to determine the size of the resistors required when forming semiconductor device structures.

During design and fabrication of a semiconductor device, the resistive structures are formed according to the desired resistance of the resistor. In some instances, large resistors are desired. To increase the amount of resistance of a resistor while minimizing the amount of space on a semiconductor substrate used by the resistor, the resistor may be configured in a serpentine manner. For example, FIG. 1A illustrates a top-down view of a conventional diffused region serpentine resistor formed on a semiconductor substrate according to conventional methods. The diffused region 12 on the semiconductor substrate 10 includes five serpentine pathways labeled a-e, respectively. Contacts 14 are in communication with the diffused region 12 at opposite ends of the resistor. The serpentine pattern of the resistor helps to increase the number of squares that can be achieved in the limited area on the semiconductor substrate 10. A cross-sectional view of the resistor along line 1B is illustrated in FIG. 1B. The diffused region 12 may include p-type or n-type doping in the silicon semiconductor substrate 10.

In many instances, glass is formed over a resistor in a semiconductor device. Glass formed over the resistive structures is often planarized by chemical mechanical planarization (CMP) techniques. However, the planarization of the glass often results in the dishing of the glass over the expanse of a resistor because of the amount of space between semiconductor features. Dishing occurs due to the large areas that are unsupported by features on a semiconductor device. For example, glass 16 disposed over the resistor illustrated in FIGS. 1A and 1B may be planarized by CMP processes, however the planarization may result in the dishing of the glass 16 as illustrated in FIG. 1C. The dishing of the glass 16 layer is undesirable and may be detrimental to the further formation of components on the semiconductor substrate 10.

Resistor configurations such as those illustrated in FIGS. 1A-1C are also prone to resistive losses at the edges of the diffused regions 12 resulting in degradation of the resistor function due to field edge effects. Such losses are also undesirable.

Therefore, it is desirable to develop resistors and methods of forming resistors that will minimize or eliminate dishing effects. It is also desirable to develop resistors and methods of forming resistors that will minimize or eliminate resistive losses due to field edge effects.

### BRIEF SUMMARY OF THE INVENTION

The present invention relates to resistors and the formation of resistors in semiconductor devices. More particularly, the present invention relates to novel resistor structures having resistive diffused regions defined by patterned polysilicon layers and methods of forming such resistors.

According to some embodiments of the invention, a resistor incorporated into a semiconductor device may include diffused regions defining a resistive path in an isolated area of a semiconductor substrate. The isolated area may include, for example, an isolated trench in the semiconductor substrate formed by a process such as shallow trench isolation (STI) or an isolated oxide feature in a semiconductor substrate. The diffused regions may be defined by a patterned polysilicon layer. The polysilicon layer may be deposited on the isolated area and patterned to define the diffused regions, which may be doped with a conductive material such as a p-type or n-type dopant. The patterned polysilicon layer pinches the diffused region allowing the formation of smaller diffused regions and more diffused regions per given area on the semiconductor substrate. Thus, more resistors or larger resistors may be incorporated with a semiconductor substrate than with conventional resistors.

The resistors of embodiments of the invention may also be less prone to dishing effects when coated with glass or another semiconductor material. The presence of the patterned polysilicon layers may support a glass or other semiconductor material deposited over the resistor. When the glass or other semiconductor material is polished such as by chemical mechanical planarization processes, the patterned polysilicon layers may decrease or prevent dishing of the glass or other semiconductor material.

The resistors of embodiments of the invention may also demonstrate improved resistance, especially with respect to the desired design resistance. The diffused regions of the resistors of the invention are pinched between the patterned polysilicon layers, which may decrease or eliminate the effects of field effects between the diffused regions. In addition, the patterning of the polysilicon layers may be accomplished such that the resistors may be positioned away from the edges of the isolated area which may result in the diminishing or elimination of field edge effects and active area effects on the resistors.

According to other embodiments of the invention, methods for forming resistors on semiconductor devices are provided. A resistor may be formed on a semiconductor device by providing an isolated area, such as an isolated trench formed by shallow trench isolation (STI) processes or an isolated oxide area. A polysilicon layer may be deposited over at least a portion of the isolated area where a resistor is to be formed. The polysilicon layer may be patterned to define one or more resistive paths in the polysilicon layer. Diffusion or implantation of a dopant, such as a conductive material, p-type dopant, or n-type dopant, over the patterned polysilicon layer may form diffused regions within the patterns of the polysilicon layer; the diffused regions may provide a resistive path for the one or more resistors. A glass or other semiconductor material may be formed over the polysilicon layer and in the patterns of the polysilicon layer to cover the diffused regions. The glass or other semiconductor material may be planarized and one or more contacts may be formed through the glass or other semiconductor material to the diffused region to provide contacts of a resistor according to embodiments of the invention.

In additional embodiments of the invention, secondary contacts to the polysilicon layers may be provided such that a voltage may be applied to the polysilicon layer. The applied voltage may improve the function of the resistor.

### BRIEF DESCRIPTION OF THE SEVERAL VIEWS OF THE DRAWINGS

While the specification concludes with claims particularly pointing out and distinctly claiming that which is regarded as the present invention, this invention can be more readily understood and appreciated by one of ordinary skill in the art from the following description of the invention when read in conjunction with the accompanying drawings in which:

FIG. 1A illustrates a top view of a conventional resistor on a semiconductor substrate;

FIG. 1B illustrates a cross-sectional view of the resistor illustrated in FIG. 1A along cross-sectional line 1B;

FIG. 1C illustrates a cross-sectional view of the resistor illustrated in FIG. 1B coated with a polished glass and exhibiting conventional dishing of the glass;

FIG. 2A illustrates a top view of a resistor on a semiconductor substrate according to embodiments of the invention;

FIG. 2B illustrates a cross-sectional view of the resistor illustrated in FIG. 2A along line 2B;

FIG. 2C illustrates a cross-sectional view of the resistor illustrated in FIG. 2B coated with glass or other semiconductor material and planarized;

FIG. 3 illustrates a top view of an alternative embodiment of a resistor according to the invention;

FIG. 4 illustrates a top view of an alternative embodiment of a resistor according to the invention;

FIG. 5 illustrates a top view of an alternative embodiment of a resistor according to the invention;

FIGS. 6A-6F illustrate cross-sectional views of a resistor according to embodiments of the invention during a process that may be used to fabricate resistors according to embodiments of the invention; and

FIG. 7 is a flow diagram of a process that may be used to fabricate resistors according to embodiments of the invention.

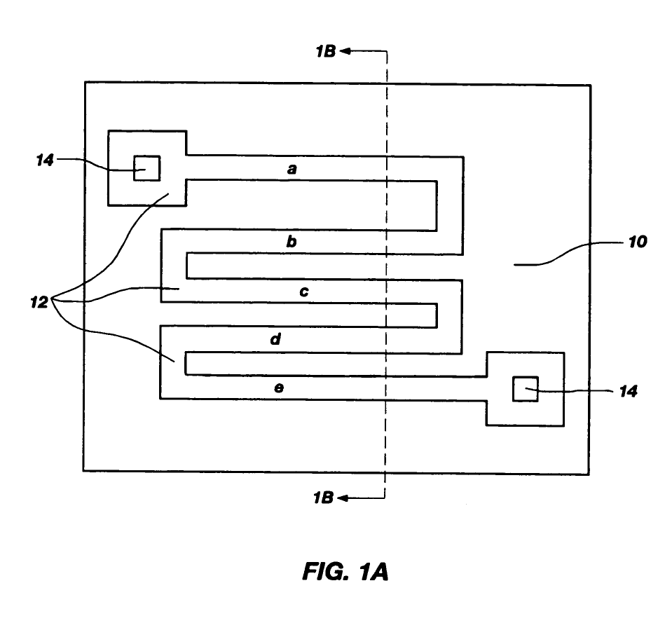

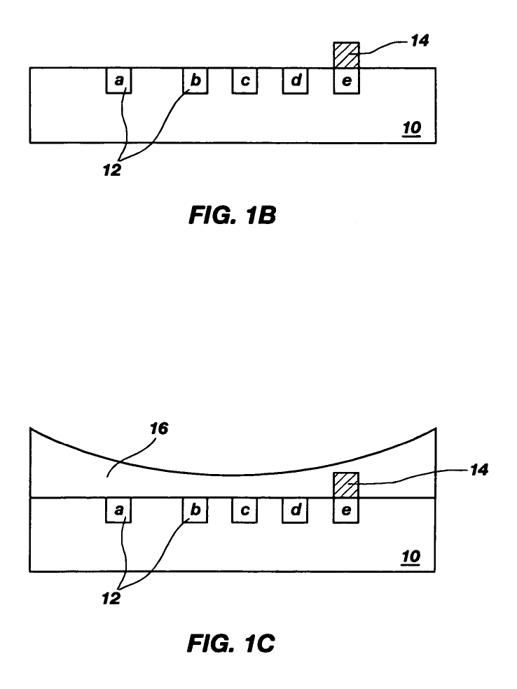

### DETAILED DESCRIPTION OF THE INVENTION

According to embodiments of the invention, a resistor may be fabricated on a semiconductor device such that polysilicon or metal walls define a diffused region which acts as the resistor. The polysilicon walls may pinch the diffused region allowing smaller widths for the resistive path to be formed on the semiconductor substrate. The polysilicon walls may also provide support to the resistor, reducing or eliminating the dishing of glass or other material formed over the resistors of the invention. The use of polysilicon patterns to define the resistive paths of the resistor may also aid in the placement of the resistor diffused regions away from any active area edges on a semiconductor substrate such that active area field effects do not alter or impact the performance of the resistor.

Resistors formed on semiconductor substrates according to embodiments of the invention include diffused regions defined by one or more polysilicon or metal patterns overlying an isolated area of a semiconductor substrate in which the diffused regions are formed. The patterns overlie at least a portion of an isolated area on a semiconductor substrate and may extend beyond the boundaries of the isolated area. Openings in the polysilicon or metal provide patterns by which the isolated area of a semiconductor substrate may be doped to form a resistive structure or resistor having a general shape of the pattern. The patterns prevent diffused regions from extending on or over the boundaries of the isolated area of the semiconductor substrate, thereby decreasing field edge effects on the resistors due to active area edge effects. In addition, the presence of the polysilicon or metal patterns provides support for glass or other semiconductor materials deposited over the resistors such that planarization of the glass or other semiconductor materials over the resistors does not result in problematic dishing of the glass or other semiconductor materials.

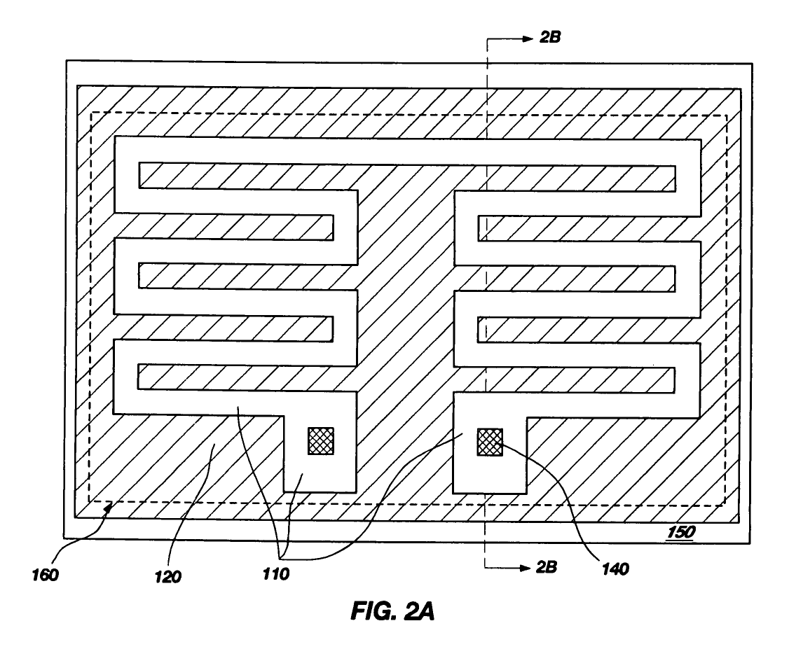

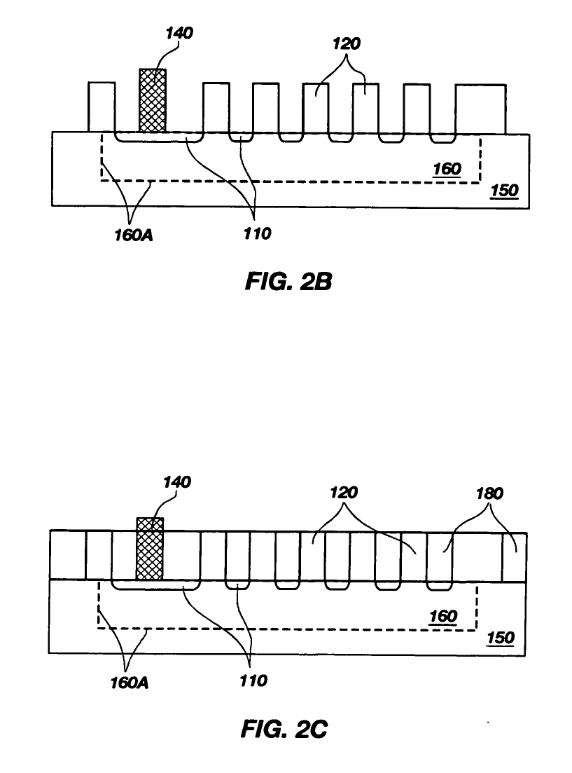

An example of a resistor according to embodiments of the invention is illustrated in FIGS. 2A-2C. A top-down view of a resistor 100 according to embodiments of the invention is illustrated in FIG. 2A. The resistor 100 may include a diffused region 110 in an isolated area 160 of a semiconductor substrate 150, the isolated area 160 being shown by the dashed line in FIG. 2A. The diffused region 110 may be defined by a patterned layer 120 overlying the semiconductor substrate 150. The patterned layer 120 may comprise a polysilicon or metal material. Contacts 140 for the resistor 100 may contact the diffused region 110 as illustrated. Additional contacts (not shown) may be formed in a semiconductor device to provide contact between the patterned layer 120 and a ground or negative voltage source to isolate the resistor 100 path formed by the diffused regions 110.

A cross-sectional view of the resistor 100, along the cross-sectional line 2B, is illustrated in FIG. 2B. The resistor 100 may include one or more diffused regions 110 having a serpentine layout as illustrated. Other layouts for the diffused regions 110 may also be formed according to embodiments of the invention. Each of the diffused regions 110 is formed in an isolated area 160 of the semiconductor substrate 150. According to embodiments of the invention, the diffused regions 110 do not intersect, cross-over, or touch the boundary 160A of the isolated area 160. The patterned layer 120 may overlie the semiconductor substrate 150 and extend beyond the boundaries 160A of the isolated area 160. The diffused regions 110 of the resistor 100 may be defined by the positioning of the patterned layer 120. For example, as illustrated in FIG. 2A, the patterned layer 120 may define a serpentine diffused region 110 for the resistor 100.

A second cross-sectional view of a resistor 100 is illustrated in FIG. 2C. The structure illustrated in FIG. 2C includes a glass layer 180 or other semiconductor material deposited in the openings of the patterned layer 120, the glass layer 180 having been planarized by known methods such as by chemical mechanical planarization (CMP). As illustrated in FIG. 2C, the presence of the patterned layer 120 may help to prevent dishing of the glass layer 180 over the area of the resistor 100, which facilitates the further production of a semiconductor device upon which the resistor 100 is formed.

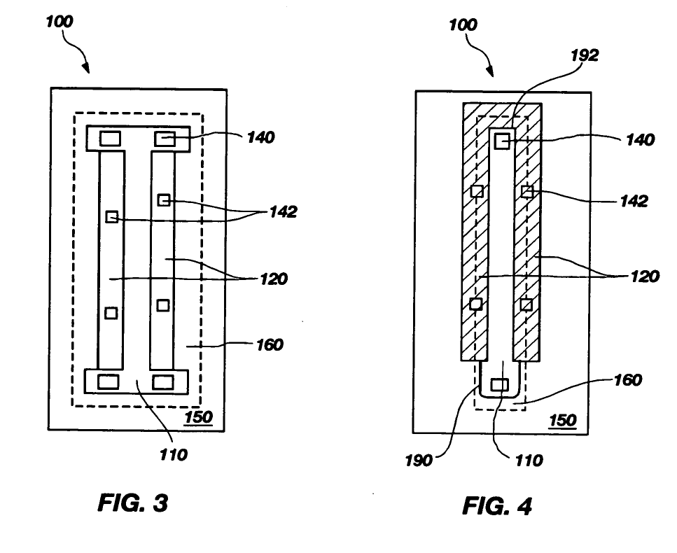

Other embodiments of resistors 100 according to the invention are illustrated in FIGS. 3-5. The resistor 100 illustrated in FIG. 3 includes patterned layers 120 overlying at least a portion of an isolated area 160 in a semiconductor substrate 150 which is illustrated by the dotted-line in FIG. 3. A diffused region 110 forming the resistive area of the resistor 100 is formed partially within boundaries defined by the patterned layers 120. The ends of the resistor 100 may be formed outside of the boundaries defined by the patterned layers 120 but within the isolated area 160 of the semiconductor substrate 150. Resistor contacts 140 may be in contact with the ends of the resistor 100 or other portions of the resistor 100. Additional contacts 142 may be in contact with the patterned layers 120 to provide an alternate voltage such as a negative voltage or ground voltage to the patterned layers 120.

Another resistor 100 according to embodiments of the invention is illustrated in FIG. 4. The resistor 100 may include one or more patterned layers 120 overlying at least a portion of an isolated area 160 of a semiconductor substrate 150 and at least a portion of the semiconductor substrate 160. A diffused region 110 forming the resistive area of the resistor 100 is formed partially within boundaries defined by the patterned layers 120. One or more ends of the resistor 100 may be formed outside of the boundaries defined by the patterned layers 120, but within the isolated area 160 illustrated by the dotted line, similar to the end 190 illustrated in FIG. 4. Alternatively, one or more ends 192 may be formed within the boundaries of the patterned layers 120. Resistor contacts 140 may be in contact with the ends of the resistor 100. Additional contacts 142 may be in contact with the patterned layers 120 to provide an alternate voltage such as a negative voltage or ground voltage to the patterned layers 120.

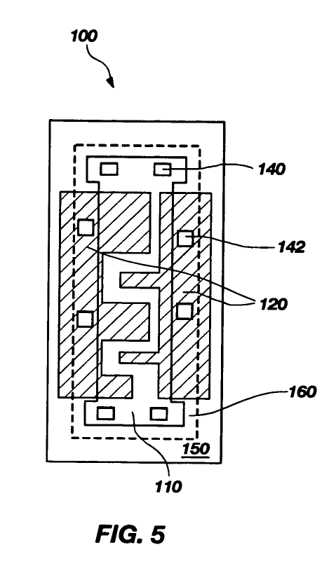

In still other embodiments of the invention, a resistor 100 may include a serpentine shape or other shape as desired. For example, the resistor 100 illustrated in FIG. 5 includes a serpentine shape having contacts 140 at opposite ends of the diffused region 110. The resistor 100 may include one or more patterned layers 120 overlying at least a portion of the isolated area 160 of a semiconductor substrate 150. A diffused region 110 forming the resistive area of the resistor 100 may be formed at least partially within the boundaries defined by the patterned layers 120. Resistor contacts 140 may be in contact with the ends of the resistor 100 and ground contacts 142 or other contacts may be in contact with the patterned layers 120.

The isolated regions 160 of the resistors 100 according to embodiments of the invention may include regions formed by shallow trench isolation (STI) processes or may include isolated oxide regions in a semiconductor substrate 150. The resistors 100 according to embodiments of the present invention may be formed in any portion of a semiconductor substrate 150 where conventional resistors are formed on semiconductor substrates or semiconductor devices.

Patterned layers 120 deposited over isolated areas 160 according to embodiments of the invention may include polysilicon layers. Patterned layers 120 formed of polysilicon may be deposited using low-pressure chemical vapor deposition (LPCVD) processes, plasma-enhanced chemical vapor deposition (PECVD) processes, laser crystallization of amorphous silicon, solid-phase crystallization of amorphous silicon, or other processes used or developed to deposit patterned layers 120 on a substrate. According to some embodiments of the invention, the patterned layers 120 may have a thickness that is between about 10 nm and about 200 nm.

According to other embodiments of the invention, the patterned layers 120 may comprise metal or metal layers. The metal may be deposited over the isolated areas 160 to form the patterned layers 120 using conventional deposition processes and in any pattern desired. In some instances, the deposited metal may have a thickness that is between about 10 nm and about 200 nm. Exemplary metals that may be used with embodiments of the invention include, but are not limited to, titanium nitride (TiN), tungsten (W), tungsten nitride (WNₓ), tungsten nitride/titanium nitride combinations or alloys (WNₓ/TiN), nickel (Ni), nickel silicide (NiSi), or nickel silicon combinations or alloys.

Dopants that may be used to form diffusion regions 110 in the isolated areas 160 may include any dopants capable of enhancing the conductive abilities of the region into which the dopants are diffused or implanted. For example, any n-type or p-type dopant used in the manufacture of semiconductor devices may be used with embodiments of the present invention. Such dopants may include, but are not limited to, boron, phosphorous, arsenic, indium, germanium, and antimony. Dopants may be implanted in the isolated areas 160 to form diffusion regions by conventional methods such as by implantation, plasma immersion doping, or solid source diffusion methods.

The shapes of the resistors 100 illustrated in FIGS. 2A, 3, 4, and 5 are understood to be representative shapes for resistors 100 that may be formed according to embodiments of the invention. It is understood that resistors 100 having other shapes and configurations may be formed according to embodiments of the invention and that patterned layers 120 may be used to define a portion of or the entire area of a diffused region 110 of the resistors 100 of the invention.

Embodiments of the invention also include methods for forming resistors. According to some embodiments of the invention, a resistor may be formed over an isolated area on a semiconductor substrate by forming one or more layers of polysilicon or metal over the substrate, patterning the polysilicon or metal layer to define a desired resistive path, implanting a dopant into the patterned area to form a resistive path in the semiconductor substrate along the patterned area, and forming two or more contacts to the resistive path to complete the resistor. The polysilicon or metal patterned over the substrate may be left on the substrate and may help to prevent the dishing of glass or other semiconductor materials deposited over the resistive areas in the polysilicon or metal pattern.

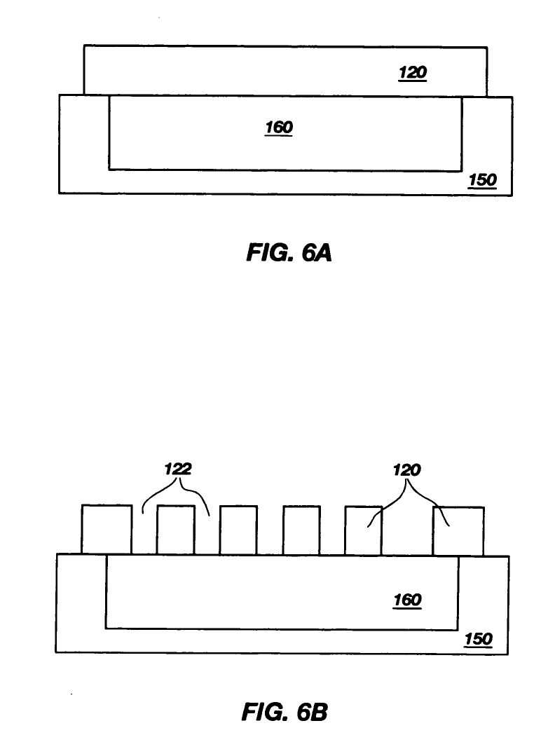

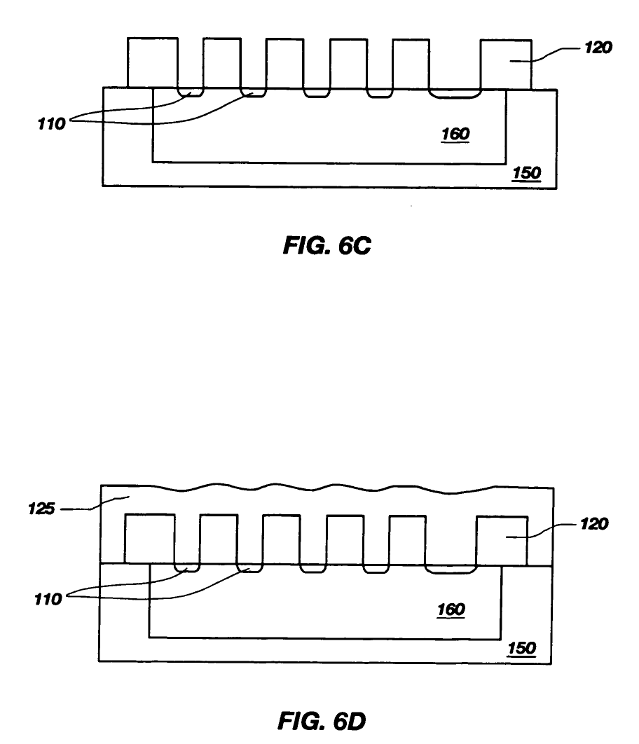

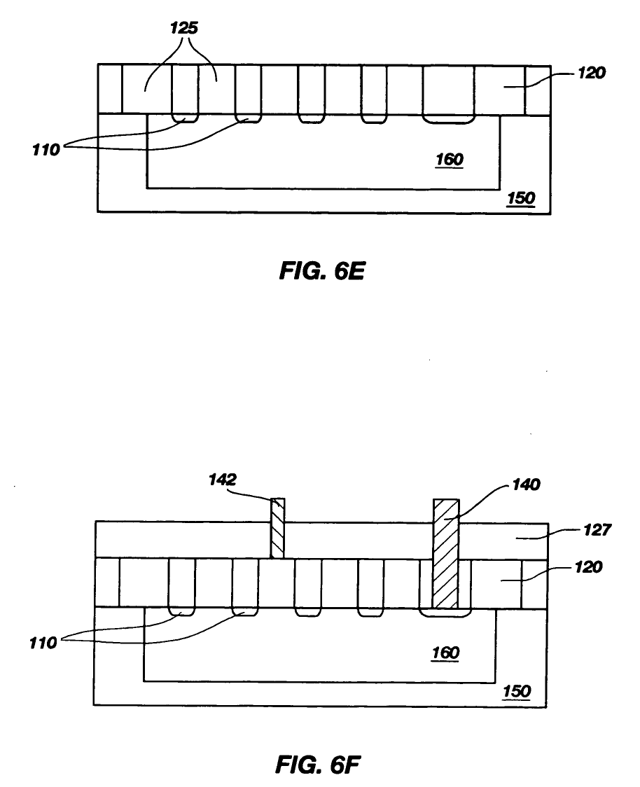

A method for forming a resistor according to embodiments of the present invention is illustrated in FIGS. 6A-6F. As illustrated in FIG. 6A, a patterned layer 120 may be deposited over a semiconductor substrate 150 having an isolated area 160. The patterned layer 120 may then be patterned to form openings 122 in the patterned layer 120 as illustrated in FIG. 6B. The openings 122 patterned in the patterned layer 120 may define one or more resistive paths. The patterning of the patterned layer 120 and the openings 122 formed in the patterned layer 120 may be selected based upon the length, width, shape, or other characteristics desired for the resistor 100. Following patterning of the patterned layer 120, dopants, such as conductive dopants or conductivity enhancing dopants, may be implanted or diffused into portions of the isolated area 160 exposed by openings 122 as illustrated in FIG. 6C. For example, dopants may be implanted through openings 122 by ion implantation or diffusion processes. The doping of portions of the isolated area 160 may form a diffused region 110 which may be used as a resistor 100.

As illustrated in FIG. 6D, the openings 122 may be filled with a glass or other semiconductor material 125 which may also overlie the diffused region 110. The glass or other semiconductor material 125 may be planarized as illustrated in FIG. 6E. Planarization of the glass or other semiconductor material 125 may be performed by chemical mechanical planarization (CMP) or by other processes used to planarize structures on semiconductor devices. As illustrated in FIG. 6F, one or more contacts 140 may be formed through the glass or other semiconductor material 125 to contact the diffused regions 110 of the resistor 100. The contacts 140 may be formed by etching away portions of the glass or other semiconductor material 125 in an opening 122 to expose a diffused region 110 and then forming a contact 140 by known methods. Additional layers of glass or other semiconductor materials 127 may be formed over the planarized glass or other semiconductor material 125 and patterned layer 120 as desired. Further, one or more secondary contacts 142 may be formed to contact the patterned layer 120 defining the diffused region 110 of the resistor 100.

Semiconductor substrates 150 having isolated regions 160 for use with embodiments of the invention may include isolated oxide regions on a semiconductor substrate 150 or an isolated trench formed by shallow trench isolation (STI) processes. For example, an isolated area 160 may be formed by first forming a trench or trenched area in a semiconductor substrate 150. The trench or trenched area may be filled with a glass using spin-on dielectric processes. The glass formed in the trench or trench area may then be planarized, finalizing the formation of an isolated area 160 in the semiconductor substrate 150.

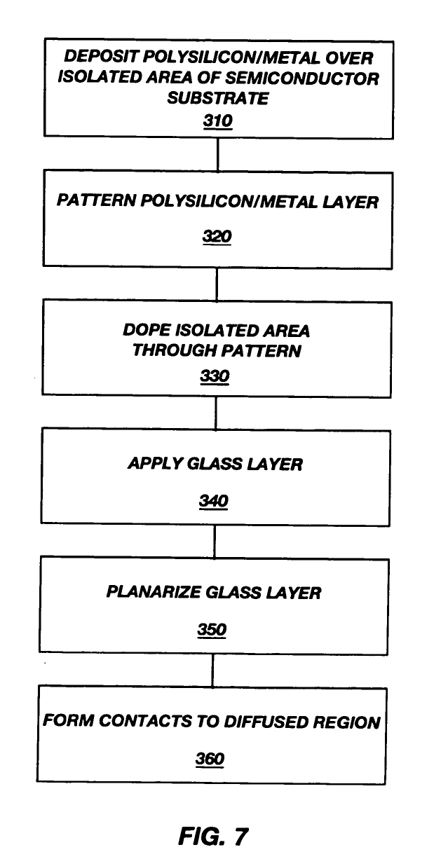

According to other embodiments of the invention, a method for forming a resistor may include the steps illustrated in the flow diagram of FIG. 7. In a first step 310, polysilicon or metal is deposited over at least a portion of an isolated area in a semiconductor substrate. The polysilicon or metal is then patterned in a second step 320 to define one or more pathways through the polysilicon or metal such that the pathways are positioned over the isolated area of the semiconductor substrate. In a third step 330, ion implantation or diffusion is used to expose the isolated areas within the pathways to a dopant to create a diffused region that may act as a resistor. Glass or other semiconductor materials may then be deposited over the diffused resistor region and the polysilicon or metal structures in a fourth step 340. Planarization 350 of the deposited glass results in a resistor which may be completed by the formation of contacts through the glass to two or more areas of the diffused region in a final step 360.

Although methods according to embodiments of the invention have been described with respect to particular fabrication steps, it is understood that additional fabrication steps may be incorporated with the steps of the inventive methods to form resistors according to embodiments of the invention. Furthermore, it is understood that additional fabrication steps may be included to provide a semiconductor substrate having an isolated region that may be used to form embodiments of the invention. For instance, a semiconductor substrate may first be exposed to a shallow trench isolation (STI) process whereby a shallow trench in a semiconductor is formed and isolated from other portions of the semiconductor substrate. STI processes are well known and may be incorporated with embodiments of the invention to provide semiconductor substrates having isolated areas upon which resistors of embodiments of the invention may be formed. In other instances, the isolated area may include an isolated oxide region in a semiconductor substrate.

According to embodiments of the invention, one or more resistors 100 may be formed in a patterned layer 120 according to embodiments of the invention. For instance, if multiple resistors are desired in a defined area on a semiconductor substrate 150, a single patterned layer 120 may be formed over the defined area. Multiple resistor shapes may then be patterned in the patterned layer 120 such that multiple resistors 100 may be formed from the patterning. The implantation or diffusion of dopants into the patterns of the patterned layer 120 may take place in a single step and the remaining fabrication steps may be completed to form multiple resistors 100 in the single patterned layer 120.

The patterned layers 120 formed according to embodiments of the invention may be positioned over an isolated area 160 on a semiconductor substrate 150 in any desired manner. The ability to position the patterned layers 120 in a desired location facilitates the placement of the resistor 100. In addition, the patterned layers 120 may be made large enough such that alteration of the placement of the patterned layers 120 due to errors in the fabrication process may not effect the placement of the resistor 100 on the semiconductor substrate 150. For example, a resistive path may be designed so that there are sufficient amounts of a patterned layer 120 around the outmost portions of the defined resistive path to compensate for errors in the fabrication placement of the patterned layer 120. If the patterned layer 120 positioning is off by a small distance, the placement of the patterns in the patterned layer 120 may still be made in the designed position relative to the semiconductor substrate because of the sufficient amount of patterned layer 120 used to coat the isolated area 160 of the semiconductor substrate 150. Thus, placement of the patterned layer 120 is not critical to the formation of the resistive paths in the patterned layer 120 as long as a sufficiently sized patterned layer 120 is used to compensate for fabrication or masking errors.

The width of resistors 100 formed according to embodiments of the invention is dependent upon the pinch region between the patterns of the patterned layer 120. The use of patterned layers 120 as pinch regions to form the diffused regions 110 and the resistor shapes may improve the number of squares that may be achieved for the given resistors 100. The improvement may be achieved because the patterned layers 120 act as gates preventing the diffusion of charge from the diffused regions to other portions of the semiconductor device or to other adjacent diffused regions 110. Thus, smaller widths for the diffused regions may be generated, resulting in resistors 100 having longer diffused regions 110 and larger squares of resistance.

In addition, charges applied to the patterned layers 120 of the resistors 100 may act to isolate the charges in the diffused regions 110, thereby preventing diffusion of current in a diffused region 110 to an adjacent diffused region 110. For example, in an MOS device formed according to embodiments of the invention, a charge applied to a patterned layer 120 creates an “off” state bias on the patterned layer 120 which prevents conduction between the isolated resistor lengths of the resistors 100.

The patterned layers 120 formed with the resistors 100 according to embodiments of the invention may also help to reduce or eliminate the dishing of glass or other semiconductor materials 125 deposited over the resistors 100 and in the openings 122 in the patterned layers 120.

Furthermore, the resistors 100 of the present invention may be formed on semiconductor substrates 150 without altering or adding to the number of fabrication steps used in a semiconductor fabrication process. Deposition of the patterned layers 120 may be performed with the deposition of other polysilicon features on the semiconductor substrate and the diffusion of the diffused regions 110 may be performed as other features of the semiconductor are being doped by diffusion or implantation. Thus, embodiments of the present invention may be incorporated with conventional semiconductor fabrication processes without adding to the costs or time required for such processes.

Having thus described certain currently preferred embodiments of the present invention, it is understood that the invention defined by the appended claims is not to be limited by particular details set forth in the above description, as many apparent variations thereof are contemplated without departing from the spirit or scope thereof as hereinafter claimed.

1. A resistor on a semiconductor substrate, comprising:
a patterned layer overlying the semiconductor substrate;
a diffused region in the semiconductor substrate defined by the patterned layer, wherein the diffused region defines a resistive path of the resistor; and
at least two contacts in communication with the diffused region.

2. The resistor of claim 1, wherein the patterned layer comprises:
a polysilicon layer overlying the semiconductor substrate; and
at least one pattern in the polysilicon layer wherein the at least one pattern exposes at least a portion of the semiconductor substrate.

3. The resistor of claim 2, wherein the exposed at least a portion of the semiconductor substrate comprises the diffused region.

4. The resistor of claim 1, wherein the patterned layer comprises a material layer having a serpentine pattern formed therein, wherein the material layer comprises a material selected from the group consisting of polysilicon, titanium nitride, tungsten, tungsten nitride, tungsten nitride/titanium nitride alloys, nickel, nickel silicide, and nickel silicon alloys.

5. The resistor of claim 1, wherein the patterned layer comprises a patterned layer having a thickness between about 10 nm and about 200 nm.

6. The resistor of claim 1, wherein the patterned layer overlying the semiconductor substrate comprises a patterned layer overlying at least a portion of an isolated area in the semiconductor substrate.

7. The resistor of claim 6, wherein the isolated area in the semiconductor substrate comprises a shallow trench isolation area in the semiconductor substrate.

8. The resistor of claim 6, wherein the isolated area in the semiconductor substrate comprises an oxide area in the semiconductor substrate.

9. The resistor of claim 6, wherein the patterned layer comprises a material selected from the group consisting of polysilicon, titanium nitride, tungsten, tungsten nitride, tungsten nitride/titanium nitride alloys, nickel, nickel silicide, and nickel silicon alloys.

10. The resistor of claim 1, wherein the diffused region in the semiconductor substrate comprises a region diffused with a dopant selected from the group consisting of a conductive dopant, a p-type dopant and an n-type dopant.

11. The resistor of claim 1, further comprising a glass layer overlying the diffused region in the semiconductor substrate.

12. The resistor of claim 1, further comprising a glass layer filling at least patterns in the patterned layer.

13. A semiconductor device, comprising:
at least one semiconductor substrate;
at least one patterned layer overlying at least a portion of the at least one semiconductor substrate;
at least one pattern in the at least one patterned layer, wherein the at least one pattern exposes at least a portion of the at least one semiconductor substrate therethrough;
a diffused region providing a resistive path in the at least one semiconductor substrate defined by the at least one pattern in the at least one patterned layer; and
at least two contacts in communication with the diffused region.

14. The semiconductor device of claim 13, wherein the at least one semiconductor substrate further comprises at least one semiconductor substrate having an isolated area in the at least one semiconductor substrate, wherein the at least one patterned layer overlies at least a portion of the isolated area.

15. The semiconductor device of claim 14, wherein the at least a portion of the at least one semiconductor substrate exposed through the at least one pattern comprises a portion of the isolated area.

16. The semiconductor device of claim 13, wherein the at least one pattern in the at least one patterned layer comprises a serpentine pattern.

17. The semiconductor device of claim 13, wherein the at least a portion of the at least one semiconductor substrate exposed through the at least one pattern comprises an isolated area.

18. The semiconductor device of claim 13, wherein the at least a portion of the at least one semiconductor substrate exposed through the at least one pattern comprises an isolated shallow trench.

19. The semiconductor device of claim 13, wherein the at least a portion of the at least one semiconductor substrate exposed through the at least one pattern comprises an oxide area.

20. The semiconductor device of claim 13, further comprising a glass layer disposed over the diffused region.

21. The semiconductor device of claim 13, further comprising a glass layer disposed in the at least one pattern in the at least one patterned layer.

22. The semiconductor device of claim 13, wherein the at least one patterned layer comprises a material selected from the group consisting of polysilicon, titanium nitride, tungsten, tungsten nitride, tungsten nitride/titanium nitride alloys, nickel, nickel silicide, and nickel silicon alloys.

23. A method of forming a resistor, comprising:
forming a layer of material over a semiconductor substrate;
patterning the layer of material to define a patterned layer having at least one pattern in the patterned layer, wherein at least a portion of the semiconductor substrate is exposed through the at least one pattern;
doping the at least a portion of the semiconductor substrate exposed through the at least one pattern; and
forming at least one contact with at least a portion of the doped semiconductor substrate.

24. The method of claim 23, further comprising providing a semiconductor substrate having an isolated region, wherein the at least one pattern in the patterned layer exposes at least a portion of the isolated region.

25. The method of claim 24, wherein the isolated region comprises a shallow trench isolation region.

26. The method of claim 24, wherein the isolated region comprises an oxide region.

27. The method of claim 23, wherein forming a layer of material over a semiconductor substrate comprises forming a layer of material having a thickness of between about 10 nm and about 200 nm over a semiconductor substrate.

28. The method of claim 23, wherein doping the at least a portion of the semiconductor substrate exposed through the at least one pattern comprises doping the at least a portion of the semiconductor substrate with a dopant selected from the group consisting of a conductive dopant, a p-type dopant, and an n-type dopant.

29. The method of claim 23, further comprising:
forming a layer of glass over the patterned layer and in the at least one pattern of the patterned layer; and
planarizing the layer of glass to an upper surface of the patterned layer.

30. The method of claim 23, further comprising forming at least one secondary contact with at least a portion of the patterned layer.

31. The method of claim 23, wherein forming a layer of material over a semiconductor substrate comprises forming a layer of material selected from the group consisting of polysilicon, titanium nitride, tungsten, tungsten nitride, tungsten nitride/titanium nitride alloys, nickel, nickel silicide, and nickel silicon alloys.
